(19) United States
(12) Patent Application Publication
(10) Pub. No.: US 2024/0153890 A1
(43) Pub. Date: May 9, 2024

(54) SEMICONDUCTOR PACKAGE ASSEMBLY AND SEMICONDUCTOR PACKAGE SUBSTRATE MODULE

(71) Applicant: King Yuan Electronics Co., Ltd., Hsin-Chu (TW)

(72) Inventors: Chia Fong CHOU, Hsin-Chu (TW); Ta Wei CHOU, Hsin-Chu (TW); Hui-Lung HSU, Hsin-Chu (TW)

(21) Appl. No.: 18/193,613

(22) Filed: Mar. 30, 2023

(30) Foreign Application Priority Data
Nov. 8, 2022 (TW) 111142654

(51) Int. Cl. H01L 23/60; H01L 23/00; H01L 23/31

(52) U.S. Cl. CPC H01L 23/60; H01L 23/3121; H01L 24/48; H01L 24/49; H01L 2224/48137; H01L 2224/49175; H01L 2924/30205

(57) ABSTRACT

The semiconductor package substrate module including a substrate, a plurality of first wires, at least one second wire, a chip, and an encapsulating body, wherein the first wires electrically connect to a first electrical contact point of the substrate and a second electrical contact point of the chip. Besides, one end of the at least one second wire connects to the at least one grounding transfer area or a first ground contact point of the substrate, and another end of the second wire extends toward a cutting area. The encapsulating body encapsulates the substrate, the first and second wires, and the chip. The semiconductor package substrate module is cut and separated along the cutting area of the substrate to form a plurality of semiconductor packaging components. A side surface of the encapsulating body exposes the first wires or at least one second wire of each semiconductor packaging component.

### CROSS-REFERENCE TO RELATED APPLICATION

This application claims priority to Taiwan Application Serial Number 111142654, filed Nov. 8, 2022, which is herein incorporated by reference in its entirety.

### BACKGROUND

### Field of Invention

The present invention relates to a semiconductor package substrate module. More particularly, the present invention relates to a semiconductor package substrate module and a package substrate module with electrostatic discharge protection.

### Description of Related Art

After semiconductor components are packaged and used in electronic products, they are easily affected by electrostatic discharge (ESD), and then the semiconductor components in electronic products are damaged by static electricity. Therefore, in the process of packaging semiconductor components, if there is no good electrostatic discharge protection design, the current generated by electrostatic discharge will interfere with the signals generated by electronic products, and cause abnormal or malfunction of electronic products. Moreover, the electric current generated by the electrostatic discharge will also cause damage to the semiconductor components in the electronic products, making the electronic products damaged and unable to operate. It is important to avoid the impact of electrostatic discharge on electronic products.

The ESD protection design of the semiconductor packaging substrate module available usually adopts an ESD protection IC or uses passive components as ESD protection design. In recent years, the electronic products tend to be miniaturized, high transmission speed and power saving. The traditional ESD protection ICs or the designs of passive components cause space constraints on miniature electronic products. And it increases extra power consumption, and increases the delay time in the signal transmission of electronic products, so that the overall efficiency of electronic products is reduced due to the electrostatic protection design. Therefore, it is indeed a need to propose a better electrostatic protection design on semiconductor packaging substrate modules to solve the above problems.

### SUMMARY

The main purpose of the present invention is to provide a semiconductor package assembly and a semiconductor package substrate module. Through the design of the semiconductor packaging substrate module, better electrostatic discharge protection capability is provided and the impact of electrostatic discharge on the internal components of the semiconductor packaging substrate module is reduced.

Another purpose of the present invention is to provide semiconductor package assembly and a semiconductor package substrate module, in which the electrostatic protection design process is relatively simple, and the quantity can be increased or decreased according to demand, the degree of freedom of the installation position is high, and the substrate does not occupy too much space.

Yet purpose of the present invention is to provide semiconductor package assembly and a semiconductor package substrate module, in which the reliability of the electrostatic protection design is better, and it will not affect the integrity of the packaged substrate module.

Yet purpose of the present invention is to provide semiconductor package assembly and a semiconductor package substrate module, which can meet the requirements of mass production and the economic benefits of lower manufacturing costs.

A semiconductor package assembly of the present invention includes a substrate comprising a plurality of first electrical contact points and at least one grounding transfer area, the first electrical contact points including a plurality of first ground contact points, and the first electrical contact points and the at least one grounding transfer area disposed respectively on a first surface of the substrate; a chip including a plurality of second electrical contact points, the chip disposed on the first surface of the substrate; a plurality of first wires electrically connecting to the corresponding first electrical contact points and the corresponding second electrical contact point; one end of at least one second wire connects to the at least one grounding transfer area or one of the first ground contact points; and an encapsulating body encapsulating the first surface of the substrate, the encapsulating body forming at least one surface on the substrate, the other end of the at least one second wire extending to and exposed from the at least one surface of the encapsulating body.

In some embodiments, wherein the at least one grounding transfer area includes at least one grounding transfer pad connecting to a ground voltage, and the least one grounding transfer pad is adjacent to one side of the substrate.

In some embodiments, wherein the substrate includes a plurality of contact pads disposed on one side of a second surface of the substrate, and the second surface is opposite to the first surface.

In some embodiments, the semiconductor package assembly further includes a protective element and a control component disposed on the substrate, the contact pads includes at least one ground contact pad electrically connecting to the at least one grounding transfer pad, and the protective element electrically connects to the at least one grounding transfer pad and the control component.

In some embodiments, the semiconductor package assembly further includes a control component disposed on the substrate, the contact pads include a plurality of ground contact pads electrically connecting to the at least one grounding transfer pad, and the at least one grounding transfer pad directly electrically connects to the control component.

In some embodiments, wherein the chip is a memory module.

In some embodiments, wherein the substrate is a circuit board or a lead frame.

In some embodiments, the semiconductor package assembly further includes a ground wire disposed on the substrate and adjacent to an edge of the substrate, and the ground wire connects to a ground voltage.

A semiconductor package substrate module of the present invention includes a substrate including a plurality of cutting areas separating the substrate into a plurality of substrate units; a plurality of semiconductor package components, and each semiconductor package component including: one of the substrate units; a plurality of first electrical contact points and at least one grounding transfer area disposed on a first surface of the substrate unit, the first electrical contact points including a plurality of first signal contact points and a plurality of first ground contact points; a chip including a plurality of second electrical contact points, the chip disposed on the first surface of the substrate unit; a plurality of first wires connecting to the corresponding first electrical contact points and the corresponding second electrical contact points; and one end of at least one second wire connecting to the at least one grounding transfer area or the first ground contact points and the other end of the at least one second wire extending toward the cutting areas; and an encapsulating body encapsulating the substrate and the semiconductor package components.

In some embodiments, wherein the other end of the at least one second wire is fixed on the cutting areas.

In some embodiments, wherein the other end of the at least one second wire extends from the cutting areas to the adjacent substrate units, and the other end of the at least one second wire is fixed to the at least one grounding transfer area or the first ground contact points in the adjacent substrate units.

In some embodiments, wherein the at least one grounding transfer area includes at least one grounding transfer pad connecting to a ground voltage, and the at least one grounding transfer pad is adjacent to one side of the substrate.

In some embodiments, wherein each substrate unit includes a plurality of contact pads disposed on one side of a second surface of the substrate unit, and the second surface is opposite to the first surface.

In some embodiments, wherein each substrate unit includes a protective element and a control component, the contact pads includes a plurality of ground contact pads electrically connecting to the at least one grounding transfer pad, and the protective element electrically connects to the at least one grounding transfer pad and the control component.

In some embodiments, wherein each substrate unit includes a control component, the contact pads includes a plurality of ground contact pads electrically connecting to the at least one grounding transfer pad, and the at least one grounding transfer pad directly electrically connects to the control component.

In some embodiments, wherein the substrate is a circuit board or a lead frame.

In some embodiments, wherein the chips are a plurality of memory modules.

In some embodiments, wherein each semiconductor package component further includes a ground wire disposed on the substrate unit and adjacent to an edge of the substrate unit, and the ground wire connects to a ground voltage.

### BRIEF DESCRIPTION OF THE DRAWINGS

The invention can be more fully understood by reading the following detailed description of the embodiment, with reference made to the accompanying drawings as follows:

FIG. 1A is a schematic diagram of a semiconductor package assembly according to an embodiment of the present invention;

FIG. 1B is a schematic diagram of a semiconductor package assembly according to an embodiment of the present invention;

FIG. 2 is a schematic diagram of a semiconductor package assembly according to another embodiment of the present invention;

FIG. 3 is a schematic diagram of a semiconductor package assembly according to another embodiment of the present invention;

FIG. 4 is a schematic diagram of an internal circuit of a semiconductor package assembly according to another embodiment of the present invention;

FIG. 5 is a schematic diagram of an internal circuit of a semiconductor package assembly according to another embodiment of the present invention;

FIG. 6 is a schematic diagram of a ground wire of a semiconductor package assembly according to another embodiment of the present invention;

FIG. 7 is a schematic diagram of a semiconductor package substrate module according to another embodiment of the present invention;

FIG. 8A is a schematic diagram of a semiconductor package assembly according to another embodiment of the present invention;

FIG. 8B is a schematic diagram of a semiconductor package assembly according to another embodiment of the present invention; and

FIG. 9 is a schematic diagram of a semiconductor package substrate module according to another embodiment of the present invention.

### DETAILED DESCRIPTION

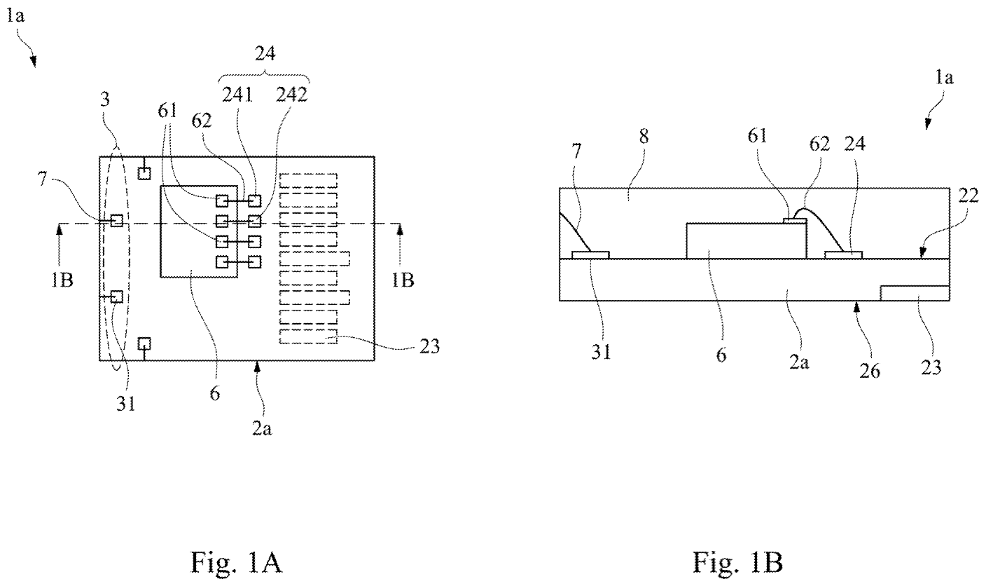

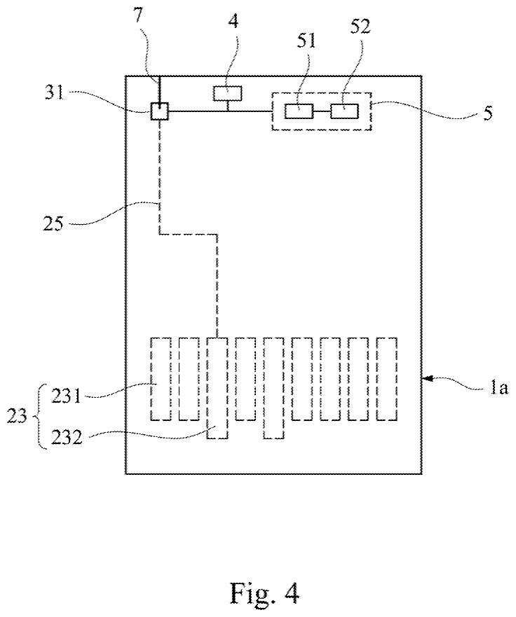

Referring to FIGS. 1A and 1B, which are a top view of an embodiment of the semiconductor package assembly 1a of the present invention and a cross-sectional view along line 1B-1B in FIG. 1A, respectively. The semiconductor package assembly 1a includes a substrate unit 2a, a chip 6, a plurality of first wires 62, at least one second wire 7, and an encapsulating body 8. In this embodiment, the substrate unit 2a is a circuit board, for example. The substrate unit 2a includes a plurality of first electrical contact points 24, at least one grounding transfer area 3, and a plurality of contact pads 23. These first electrical contact points 24 and the at least one grounding transfer area 3 are disposed respectively on a first surface 22 of the substrate unit 2a, and the first electrical contact points 24 and the at least one grounding transfer area 3 are disposed adjacent to a side of the first surface 22. The first electrical contact points 24 include a plurality of first signal contact points 242 and a plurality of first ground contact points 241. The grounding transfer area 3 includes at least one grounding transfer pad 31. The contact pads 23 include a plurality of signal contact pads 231 and a plurality of grounding contact pads 232. The contact pads 23 are disposed on one side of a second surface 26 of the substrate unit 2a. The first surface 22 and the second surface 26 of the substrate unit 2a are disposed opposite to each other. The grounding transfer pad 31 in the grounding transfer area 3 electrically connects to the grounding contact pads 232 through the wiring 25 in the circuit board (as shown in FIG. 4). The first electrical contact points 24 electrically connect to the corresponding contact pads 23. The chip 6 includes a plurality of second electrical contact points 61 and a plurality of first wires 62. The second electrical contact points 61 are disposed on a surface of the chip 6, and the chip 6 is disposed on the first surface 22 of the substrate unit 2a. The first wires 62 electrically connect to the corresponding first electrical contact points 24 of the substrate unit 2a and the corresponding second electrical contact points 61 of the chip 6, so that the chip 6 and the substrate unit 2a can connect and transmit signals through the first wires 62. One end of the second wire 7 connects to the corresponding grounding transfer pad 31 in the grounding transfer area 3 or the corresponding first ground contact points 241. The other end of the second wire 7 extends toward the side of the substrate unit 2a. An encapsulating body 8 encapsulates the first surface 22 of the substrate unit 2a, and the encapsulating body 8 encapsulates the chip 6, the first wires 62, the second wire 7, the first electrical contact points 24, and the grounding transfer area 3 on the first surface 22 to avoid air, moisture and other external disturbances affecting the components on the first surface 22 of the substrate unit 2a. The encapsulating body 8 forms at least one surface on the substrate unit 2a, wherein the other end of the second wire 7 extending toward the side of the substrate unit 2a is exposed to at least one surface of the encapsulating body 8 and is in contact with the air. The grounding transfer pad 31 of at least one grounding transfer area 3 or the first ground contact points 241 is electrically extended to the surface of the encapsulating body 8 through the second wire 7.

The grounding transfer pad 31, the first ground contact point 241, and the grounding contact pads 232 of the substrate unit 2a electrically connect to each other through the ground wire 25 connecting to a ground voltage (as shown in FIG. 4), and the second wire 7 also connects to the ground voltage. The other end of the second wire 7 is in contact with the air, which can effectively solve the problem of electrostatic discharge. When an object charged with static electricity approaches the semiconductor package assembly 1a, there is a potential difference between the object charged with static electricity and the semiconductor package assembly 1a. Since one end of the second wire 7 connects to the ground voltage, and the second wire 7 is a thin metal wire, the voltage difference between the ground voltage and the object charged with static electricity is enough to make the other end of the second wire 7 exposed to the air to air discharge, thereby neutralizing static electricity through the second wire 7. It also reduces the voltage difference between the object charged with static electricity and the ground voltage, and reduces the damage of static electricity to the semiconductor package assembly 1a. Moreover, when the object charged with static electricity touches the semiconductor package assembly 1a, because the second wire 7 is made of metal and exposed to the surface of the encapsulating body 8, and the resistance value of the second wire 7 is smaller than that of the encapsulating body 8 and has better conductivity, the second wire7 can quickly guide the static electricity to the ground, so as to avoid damage to the chip 6 inside the semiconductor package assembly 1a by objects charged with static electricity.

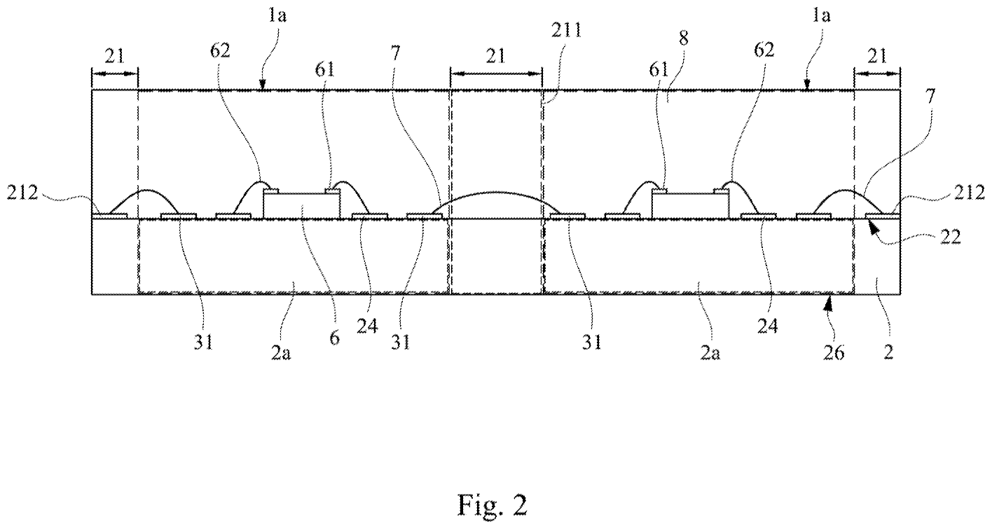

Please refer to FIGS. 1A, 1B, and 2. In one embodiment of the present invention, a plurality of semiconductor package assembly 1a are separated by cutting areas 21 as shown in the figures, which means that two semiconductor package assemblies 1a are adjacently arranged across the cutting areas 21. The grounding transfer pad 31 in at least one grounding transfer area 3 on the semiconductor package assembly 1a is disposed on the side of the substrate unit 2a, so that the grounding transfer pad 31 in at least one grounding transfer area 3 of the adjacent semiconductor package assembly 1a are respectively located on opposite sides of the cutting area 21. The second wire 7 connects one end to the grounding transfer pad 31, which is in at least one grounding transfer area 3 on the substrate unit 2a on one side of the cutting area 21 by wire bonding. The second wire 7 then extends and crosses the cutting area 21. The other end of the second wire 7 connects to the grounding transfer pad 31 in at least one grounding transfer area 3 on the substrate unit 2a on the other side of the cutting area 21, so that the second wire 7 extends between two adjacent semiconductor package assemblies 1a. The configuration of the second wire 7 in the two semiconductor package assemblies 1a can be completed at the same time through a single second wire 7.

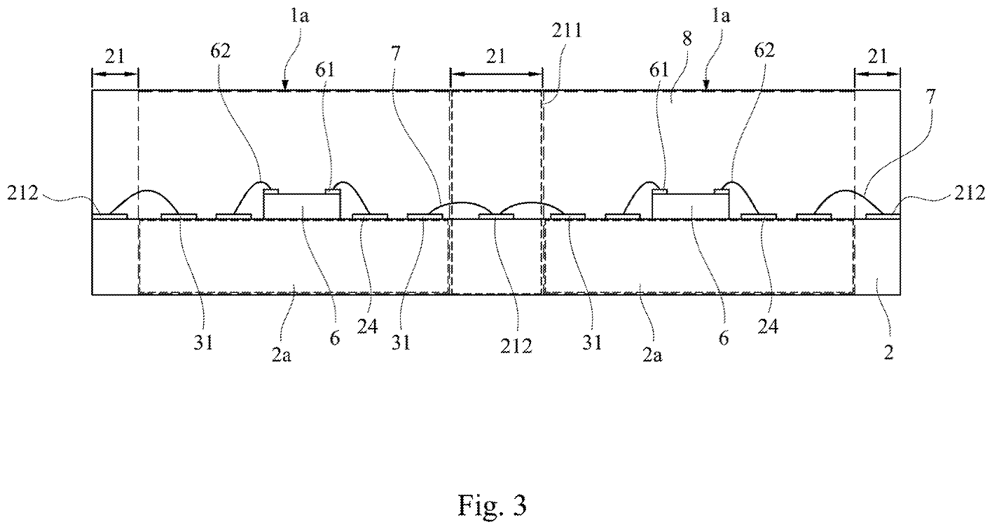

Please refer to FIGS. 1A, 1B, and 3. In another embodiment of the present invention, a plurality of welding pads 212 are disposed on the cutting area 21 adjacent to the semiconductor package assembly 1a as shown in figures. The second wire 7 connects one end to the grounding transfer pad 31 on the substrate unit 2a by wire bonding. The second wire 7 then extends to the cutting area 21. The other end of the second wire 7 connects to the welding pads 212 on the cutting area 21. The second wire 7 extends out of the semiconductor package assembly 1a through the welding pads 212 on the cutting area 21. This connection method does not need to span the entire cutting area. It can not only effectively shorten the length of the second wire 7, but prevent the second wire 7 from collapsing, deforming and breaking when it crosses a long distance, thereby causing a short circuit or even interlacing with other welding wires to cause a short circuit, and can also improve the reliability of production.

Please refer to FIGS. 1A, 1B, 2, and 3. The encapsulating body 8 encapsulates the first surface 22 of the substrate unit 2a, and seals the chip 6, the first wires 62, the second wire 7, the first electrical contact points 24, and at least one grounding transfer area 3. The encapsulating body 8 further covers and seals the cutting area 21 adjacent to the semiconductor package assembly 1a, so that the chip 6, the first wires 62, the second wire 7, the first electrical contact point 24, and the grounding transfer area 3 can be completely encapsulated by the encapsulating body 8. The components inside the semiconductor package assembly 1a can be fully protected by setting the encapsulating body 8.

The cutting areas 21 are disposed between the multiple semiconductor package assemblies 1a. Both sides of the cutting area 21 are cutting lines 211. The cutting lines 211 are disposed along an edge of the semiconductor package assembly 1a. After the semiconductor package assembly is wrapped by the encapsulating body 8, the encapsulating body 8, the second wire 7, and the substrate 2 will be cut off with a knife according to the cutting lines 211, so that the semiconductor package assembly 1a forms an independent unit. The second wire 7 extending out of the cutting line 211 is exposed to the surface of the encapsulating body 8 after cutting, and the second wire 7 is in contact with ambient air.

After multiple semiconductor package assemblies 1a are cut, one end of the second wire 7 connects to the grounding transfer area 3, and the other end of the second wire 7 is exposed to the encapsulating body 8 and is in contact with the air. The position where the other end of the second wire 7 is exposed to the encapsulating body 8 is higher than the first surface 22 of the substrate unit 2a, and the grounding transfer pad 31 in the grounding transfer area 3 does not connect to the edge of the substrate unit 2a. A distance between the position of the grounding transfer pad 31 and the edge of the substrate unit 2a makes the surface of the cut edge of the substrate unit 2a flat. After the substrate unit 2a is encapsulated by the encapsulating body 8, the adhesion between the edge of the substrate unit 2a and the encapsulating body 8 is better, and it is not easy to generate pores, thereby avoiding the problem of moisture entering the substrate unit 2a and causing circuit oxidation and corrosion. The second wire 7 is only exposed to the cut surface of the encapsulating body 8. The rest of the second wire 7 is completely and tightly covered by the encapsulating body 8, so that the second wire 7 will not guide moisture to cause oxidation of the substrate unit 2a. The second wire 7 is made of gold (Au) or silver (Ag), which has good corrosion resistance and conductivity, and has a better effect of guiding static electricity. In addition, in other embodiments, the second wire 7 can also be made of copper (Cu), aluminum (Al), or an alloy formed of two or more metal materials.

Since the grounding contact pad 232 is used for grounding and provides a ground voltage. The grounding transfer pad 31 connects to the grounding contact pad 232 through the wiring 25 in the circuit board, so that the grounding transfer pad 31 in at least one grounding transfer area 3 and the grounding contact pad 232 have the same ground voltage. One end of the second wire 7 connects to at least one grounding transfer pad 31 in the grounding transfer area 3, so that the electrical properties of the second wire 7 and the grounding contact pad 232 are the same. And the second wire 7 is exposed on the surface of the encapsulating body 8. When an object is close to the semiconductor package assembly 1a, because the object accumulates a large amount of static electricity, the voltage of the object and the ground voltage have a large voltage difference. The second wire 7 is exposed on the surface of the encapsulating body 8 and is in contact with the air, and the second wire 7 is a metal wire with a thinner wire diameter. When the voltage difference between the voltage of the object and the ground voltage reaches a certain level, the tip of the second wire 7 exposed on the surface of the encapsulating body 8 will start to accumulate charges, and the charges will be released into the air or on the object. The voltage difference between the object and the semiconductor package assembly 1a is reduced by neutralizing the charge state of the object. Moreover, when an object touches the second wire 7 exposed on the surface of the encapsulating body 8, the object accumulates a large amount of static electricity, resulting in a higher voltage, while the second wire 7 has a lower ground voltage, so that the static electricity on the object will be guided to at least one grounding transfer area 3 by the second wire 7. The circuit in the substrate unit 2a then guides the static electricity to the grounding contact pad 23 and then grounds. This design exposed by the second wire 7 quickly guides and grounds the static electricity, effectively protects the components in the chip of the semiconductor package assembly 1a, and avoids the signal interference caused by the static electricity to the semiconductor package assembly 1a.

In the present invention, the semiconductor package assembly 1a is, for example, a product of a memory card, and the chip 6 may be a memory chip. The chip 6 connects the second electrical contact point 61 to the first electrical contact point 24 through the first wires 62, and the first electrical contact point 24 electrically connects to the contact pad 23 by the wiring 25 in the substrate unit 2a.

Please refer to FIGS. 1A, 1B, and 4. The semiconductor package assembly 1a further includes a control component 5 and a protective element 4. The control component 5 and the protective element 4 are disposed on the first surface 22 of the substrate unit 2a, respectively. The contact pad 23 is disposed on one side of the second surface 26 of the substrate unit 2a. The control component 5 includes a control switch 51 and a controller 52. The control component 5 is used to control the data access and read/write actions of the chip 6 through the control switch 51 and the controller 52, so as to achieve the control of signal transmission. The contact pad 23 includes a plurality of grounding contact pad 232 connecting to at least one grounding transfer pad 31, so that the grounding transfer pad 31 can connect to a ground voltage by the grounding contact pad 232. The protective element 4 respectively electrically connects between at least one grounding transfer pad 31 and the control component 5. The grounding transfer pad 31 on the first surface 22 of the substrate unit 2a connects to a second wire 7, and is encapsulated by encapsulating body 8, thereby encapsulating the control component 5, the protective element 4, the grounding transfer pad 31, and the second wire 7. The second wire 7 is exposed to a surface of the encapsulating body 8 in contact with the air, thereby providing electrostatic protection. The protective element 4 is a passive element that provides electrostatic protection, and can prevent electrostatic discharge from causing damage to the above mentioned elements of the semiconductor package assembly 1a. The protective element 4 is, for example, a transient voltage suppressor (TVS) diode. Under the design that the transient voltage suppressor diode connects in parallel with the control component 5 or the chip 6, when the static electricity or abnormal power supply generates a surge overvoltage to the circuit, the transient voltage suppressor diode activates and consumes the surge current, thereby clamping the overvoltage to destroy the control component 51, the chip 6 and other components on the semiconductor package assembly 1a. The grounding transfer pad 31 is used to connect the second wire 7 to the surface structure of the encapsulating body 8 and the design of the protective element 4 is added. The semiconductor package assembly 1a is protected from static electricity with a double protection mechanism and has better reliability.

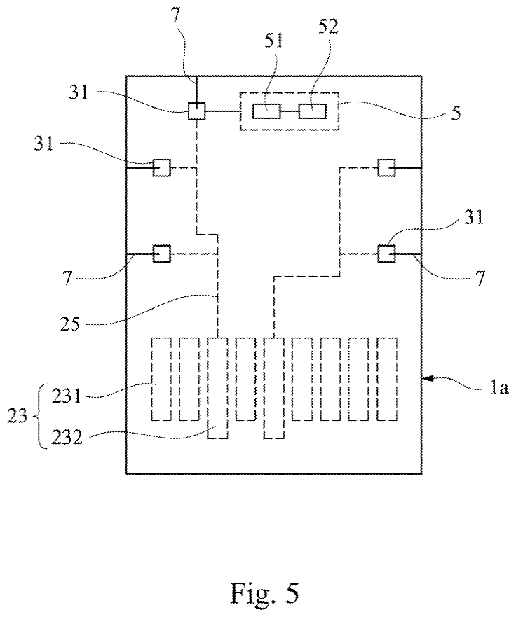

Please refer to FIGS. 1A, 1B, and 5. The semiconductor package assembly 1a further includes a control component 5 disposed on the substrate unit 2a as shown in figures. The control component 5 includes a control switch 51 and a controller 52. The control component 5 controls the action of the chip 6 through the control switch 51 and the controller 52 to achieve the control of signal transmission, and the substrate unit 2a has a structure in which multiple groups of grounding transfer pad 31 connect to the second wire 7. The control component 5, the grounding transfer pad 31, and the second wire 7 are all disposed on the first surface 22 of the substrate unit 2a, and are encapsulated by the encapsulating body 8, thereby encapsulating the control component 5, the grounding transfer pad 31, and the second wire 7. The contact pad 23 includes a plurality of grounding contact pads 232 disposed on the second surface 26 of the substrate unit 2a. The grounding transfer pads 31 electrically connect to the grounding contact pad 232, respectively. The grounding transfer pad 31 can connect to the ground voltage by the grounding contact pad 232, and the grounding transfer pad 31 directly electrically connects to the control component 5. The multiple grounding transfer pads 31 in this embodiment are respectively disposed adjacent to sides of the substrate unit 2a, and the second wire 7 is exposed to the surface of the encapsulating body 8 on the sides of the substrate unit 2a. The design of the multiple groups of grounding transfer pad 31 connecting to the second wire 7 achieves the functions of quickly neutralizing static electricity and guiding static electricity grounding, thereby replacing the protective element 4 for electrostatic protection and reducing the manufacturing cost of the semiconductor package assembly 1a.

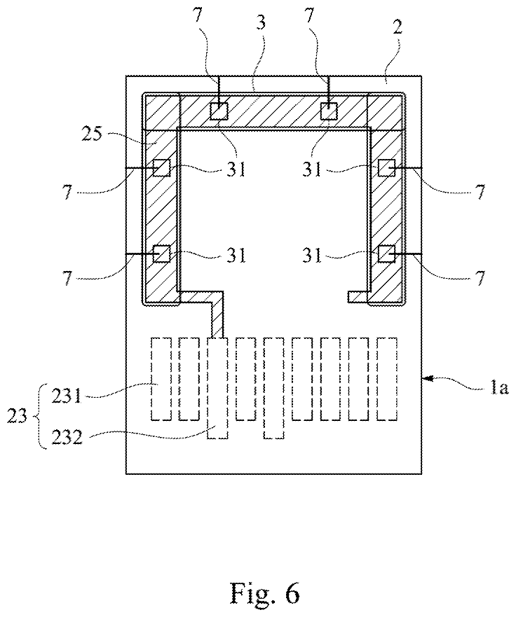

Referring to FIG. 6, the semiconductor package assembly 1a includes a substrate unit 2a, a contact pad 23, a grounding transfer pad 31, a ground wire 25, and a second wire 7. The contact pad 23, the ground wire 25, and the grounding transfer pad 31 are disposed on the substrate unit 2a. The area of the ground wire 25 or the grounding transfer pad 31 on the substrate unit 2a forms a grounding transfer area 3. The contact pad 23 includes a signal contact pad 231 and grounding contact pad 232. The ground wire 25 is disposed on the substrate unit 2a and electrically connects to the grounding transfer pad 31 and the grounding contact pad 232. The second wire 7 electrically connects to the ground wire 25 by wire bonding. One end of the second wire 7 connects to the grounding transfer pad 31, and the other end extends out the edge of the substrate unit 2a. After the encapsulating body 8 encapsulates the substrate 2, the contact pad 23, the grounding transfer pad 31, the ground wire 25, and the second wire 7, and then cut along the edge of the substrate 2, the other end of the second wire 7 is exposed on the side of the semiconductor package assembly 1a. The ground wire 25 is disposed on the side of the substrate unit 2a and adjacent to the edge of the substrate, but the ground wire 25 and the edge of the substrate do not contact each other. The grounding transfer pad 31 is disposed on the ground wire 25 or on one side of the grounding transfer pad. The grounding transfer pad 31 will not be in contact with the edge of the substrate, so that the combination between the encapsulating body 8 and the substrate is relatively tight. The cutting surface of the semiconductor package assembly 1a after cutting has a better waterproof function, thereby preventing water vapor from entering the semiconductor package assembly 1a from the gaps between the ground wire 25 and the substrate unit 2a, the encapsulating body 8, or the grounding transfer pad 31, and shortening the service life of the semiconductor package assembly 1a. The ground wire 25 is disposed on the side of the substrate unit 2a and surrounds the signal lines on the substrate. When the semiconductor package assembly 1a is affected by static electricity or electromagnetic interference, the configuration of the ground wire 25 and the second wire 7 can quickly transmit the signal of static electricity or interference to the grounding contact pad 232 for grounding, thereby protecting the electronic components on the semiconductor package assembly 1a and from being damaged by static electricity and effectively reducing the interference to the signal in the semiconductor package assembly 1a. In addition, the second wire 7 can increase or decrease the quantity according to the specification of electrostatic protection. When the number of the second wire 7 is large, the semiconductor package assembly 1a can withstand a large amount of static electricity and maintain normal operation. In another embodiment, the second wire 7 can directly connect to the ground wire 25 in the grounding transfer area 3 without the transfer of the grounding transfer pad 31. The connection between the second wire 7 and the ground wire 25 is relatively simple, and has the advantage of reducing the manufacturing process of the grounding transfer pad 31.

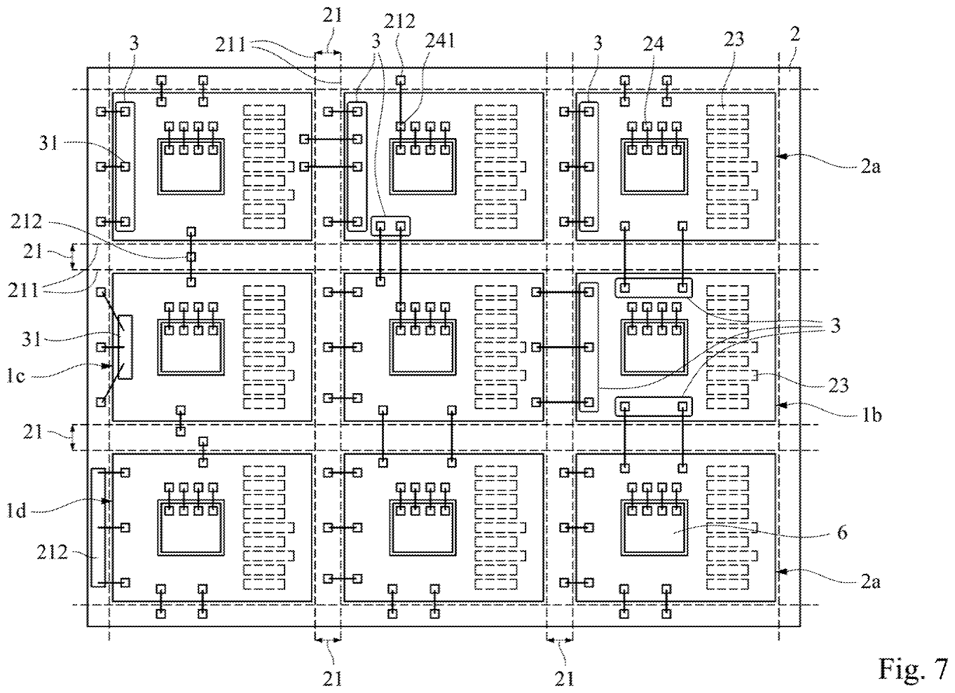

Please refer to FIGS. 1A, 1B, 2, 3, and 7. FIG. 7 is a schematic diagram of a semiconductor package substrate module 1. The semiconductor package substrate module 1 includes a substrate 2, a plurality of semiconductor package assemblies 1a, 1b, 1c, 1d, and an encapsulating body 8. In this embodiment, the substrate 2 can be a circuit board, for example. The substrate 2 includes a plurality of cutting areas 21 and a plurality of substrate units 2a. The cutting area 21 is the area formed by two opposite cutting lines 211 or the area where the cutting lines 211 are on the opposite side of the substrate unit 2a. The cutting area 21 separates the substrate 2 into plural substrate units 2a. The semiconductor package assembly 1a includes a substrate unit 2a, a chip 6, first wires 62, and a second wire 7. The substrate unit 2a includes a plurality of first electrical contact points 24 and at least one grounding transfer area 3. The first electrical contact points 24 include a plurality of first signal contact points 242 and a plurality of first ground contact points 241. The first electrical contact points 24 and the at least one grounding transfer area 3 are disposed respectively on the first surfaces 22 of the substrate units 2a. The grounding transfer area 3 is disposed adjacent to the edges of the sides of the substrate units 2a. The at least one grounding transfer area 3 may be disposed at a position close to the cutting line 211. The chip 6 includes a plurality of second electrical contact points 61. The second electrical contact points 61 are disposed on the surface of the chip 6, and the chip 6 is disposed on the first surface 22 of the substrate unit 2a. A plurality of first wires 62 electrically connect to the first electrical contact points 24 of the substrate unit 2a and the second electrical contact point 61 of the chip 6 by soldering. The signal between the chip 6 and the substrate unit 2a is sent by the first wires 62. The second wire 7 connects one end to the grounding transfer pad 31 in the at least one grounding transfer area 3 or the first ground contact point 241 by welding. The other end of the second wire 7 extends toward the cutting area 21 outside the substrate unit 2a, and the other end of the second wire 7 is fixed to cutting area 21 or at least one grounding transfer area 3 or the first ground contact point 241 in another substrate unit 2a. The encapsulating body 8 wraps the substrate 2 and the packaging components, so that each substrate unit 2a, chip 6, first wire 62, second wire 7, first electrical contact point 24, second electrical contact point 61, and at least one grounding transfer area 3 are covered by the encapsulating body 8. It may avoid being damaged by touching after being encapsulated by the encapsulating body 8.

In one embodiment, one end of the second wire 7 of the semiconductor package assembly 1b in the semiconductor package substrate module 1 connects to the grounding transfer pad 31 in at least one grounding transfer area 3, and the other end of the second wire 7 connects to grounding transfer pad 31 in the grounding transfer area 3 on another adjacent substrate unit 2a. The grounding transfer area 3 on two adjacent substrate units 2a directly connects to each other through the second wire 7. Since the second wire 7 directly cross the cutting area 21 with a single wire, and completes the configuration of the second wire 7 on two substrate units 2a at the same time, the process of disposing the welding pad 212 in the cutting area 21 may be omitted, and the time for segmented wire bonding may be saved, thereby having the advantage of saving time.

In one embodiment, one end of the second wire 7 of the semiconductor package assembly 1c in the semiconductor package substrate module 1 connects to the grounding transfer pad 31 in at least one grounding transfer area 3. The other end of the second wire 7 connects to the welding pad 212 in the cutting area 21 outside of the substrate unit 2a. Each grounding transfer pad 31 corresponds to the welding pad 212 respectively, and the welding pad 212 disposed in the cutting area 21 are respectively adjacent to the cutting line 211, which can shorten the distance between the grounding transfer pad 31 and the welding pad 212. In addition to effectively shortening the length of the second wire 7, it can also avoid wire collapse cause by the second wire 7 when it spans a long distance, short circuit cause by contacting with the substrate, or even short circuit caused by interlacing with other welding wires, thereby improving production reliability and saving the use cost of the second wire 7.

In one embodiment, the second wire 7 in different substrate units 2a can connect to the same welding pad 212 in the cutting area 21. The second wires 7 are fixed together on the same welding pad 212, and there is no need to design a dedicated welding pad 212 for each second wire 7, which can reduce the number of the welding pads 212 in the cutting area 21 and lower the production cost.

In one embodiment, in order to increase the number of the second wire 7 in the semiconductor package assembly 1c, 1d, the shape of the grounding transfer pad 31 or the welding pad 212 may be changed, such as increasing the area range or changing the disposing position, so as to meet the position configuration requirements of the second wire 7. One ends of the second wires 7 connect to each grounding transfer pad 31 in at least one grounding transfer area 3 or connect to the same grounding transfer pad 31, and the other ends of the second wires 7 connects to the same welding pad 212 or different welding pads 212 in the cutting area 21 outside the substrate units 2a. The welding pad 212 in the cutting area 21 is disposed between two grounding transfer areas 3 on two adjacent substrate units 2a. The positions of the welding pads in the cutting area 21 can be adjusted according to the design requirements or the welding pads 212 with a larger area can be formed. One ends of the second wires 7 are fixed to each grounding transfer pad 31 of the grounding transfer area 3. The second wires 7 can be fixed on different welding pads 212 or different positions in the one welding pad 212 according to the design requirements. The second wires 7 have a higher degree of freedom in the side of the substrate 2. The number of welding pads 212 may be also reduced, and the welding pads 212 may be further disposed close to the cutting lines 211 on both sides of the cutting area 21. The welding pads 212 disposed close to the cutting lines 211 on both sides of the cutting area 21 can effectively shorten the length of the second wire 7 connecting to the grounding transfer area 3 and reduce the number of the welding pad 212 in the design. The reduction in the number of welding pads 212 and the shortening of the length of the second wire 7 can achieve the advantage of saving the use cost of the second wire 7.

In the present invention, the grounding transfer pad 31 in the grounding transfer area 3 is disposed close to the edge of the substrate unit 2a, so that the second wire 7 extends out of the edge of the substrate unit 2a, and can reduce the length of the second wire 7. In one embodiment, the grounding transfer area 3 is for example disposed adjacent to any side of the substrate unit 2a. In another embodiment, the grounding transfer area 3 is for example disposed on any two sides adjacent to the substrate unit 2a. In another embodiment, the grounding transfer area 3 is for example disposed on any three sides adjacent to the substrate unit 2a. In another embodiment, the grounding transfer area 3 is for example disposed on each side adjacent to the substrate unit 2a. The position of the grounding transfer area 3 can be adjusted according to different circuit wiring design on the substrate unit 2a, or the grounding transfer area 3 can be disposed according to the sides of the substrate unit 2a that is easily affected by electrostatic discharge, so as to achieve the effect of electrostatic protection.

In the embodiment of the present invention, the second wire 7 connects the grounding transfer pad 31 in the substrate unit 2a and extends to the welding pad 212 outside the substrate unit 2a. The quantity relationship between the grounding transfer pad 31 and the welding pad 212 may be, for example, one-to-one, many-to-one, or one-to-many. When the quantity relationship between the grounding transfer pad 31 and the welding pad 212 is one-to-one, the grounding transfer pad 31 and the welding pad 212 can connect each other through a second wire 7. When the quantity relationship between the grounding transfer pad 31 and the welding pad 212 is many-to-one, the grounding transfer pads 31 connect to the one welding pad 212 using a corresponding number of the second wire 7. When the quantity relationship between the grounding transfer pad 31 and the welding pad 212 is one-to-many, one grounding transfer pad 31 connects to the welding pads 212 through the second wire 7 corresponding to the number of the welding pads 212. The number of the second wire 7 may be controlled by adjusting the number of the grounding transfer pad 31 and the welding pad 212. The quantity of the grounding transfer area 3 and the welding pad 212 may be flexibly adjusted according to the space limitation of the substrate 2 and the substrate unit 2a, so as to meet the space utilization conditions of various circuits on substrate 2 and realize the function of electrostatic protection.

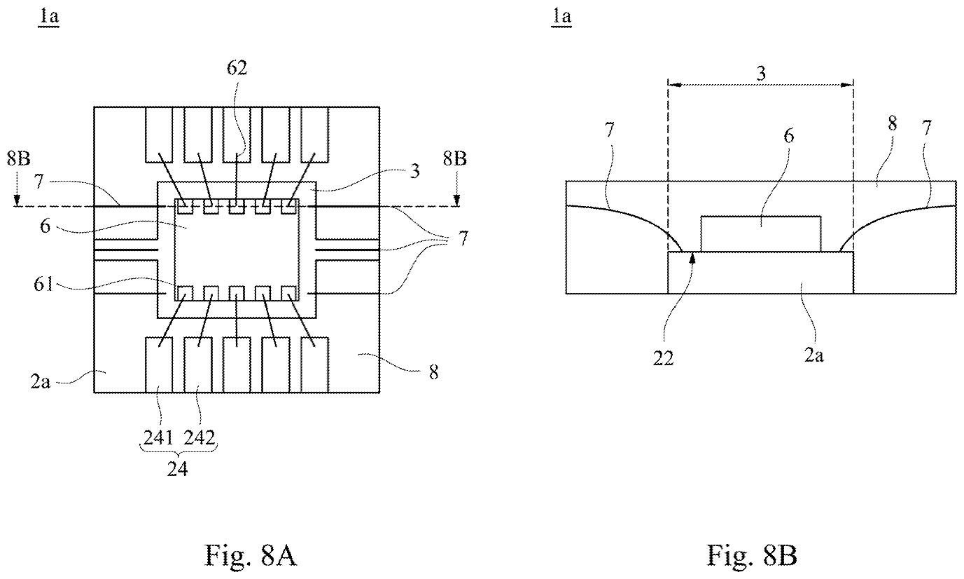

FIGS. 8A and 8B are respectively a top view of another embodiment of the semiconductor package assembly 1a of the present invention and the cross-section view along line 8B-8B in FIG. 8A. The semiconductor package assembly 1a includes a substrate unit 2a, a chip 6, a plurality of first wires 62, at least one second wire 7, and an encapsulating body 8. The substrate unit 2a in the embodiment is a lead frame, for example. The substrate unit 2a includes a plurality of first electrical contact points 24 and at least one grounding transfer area 3. The first electrical contact points 24 are disposed on the pin of the lead frame. The first electrical contact points 24 include a plurality of first ground contact points 241 and a plurality of first signal contact points 242. The first electrical contact points 24 and the at least one grounding transfer area 3 are disposed on the first surface 22 of the substrate unit 2a. There is a space between the grounding transfer area 3 and the first electrical contact points 24, so that the grounding transfer area 3 and the first electrical contact points 24 do not directly connect to each other. The chip 6 includes a plurality of second electrical contact points 61. The chip 6 is disposed on the first surface 22 of the substrate unit 2a, and the chip 6 is further disposed in the grounding transfer area 3 of the first surface 22. The first wires 62 respectively electrically connect to the first electrical contact points 24 of the substrate unit 2a and the second electrical contact points 61 of the chip 6. The encapsulating body 8 encapsulates the chip 6 and the first surface 22 of the substrate unit 2a, the first wires 62, and the second wire 7. The encapsulating body 8 forms at least one surface on the substrate unit 2a. One end of the at least one second wire 7 connects to at least one grounding transfer area 3 or the first ground contact points 241, and the other end of the at least one second wire 7 extends and is exposed from the surface of the encapsulating body 8. In one preferred embodiment, the material of the lead frame may be copper (Cu), iron (Fe), nickel (Ni), aluminum (Al), or an alloy made of at least one of the above materials. The first electrical contact points 24 may be formed on the pins of the lead frame through the electroplating process. The material of the first electrical contact points 24 may be gold (Au), silver (Ag), copper (Cu), tin (Sn), nickel (Ni), bismuth (Bi), or a conductive alloy composed of at least one of the above metals.

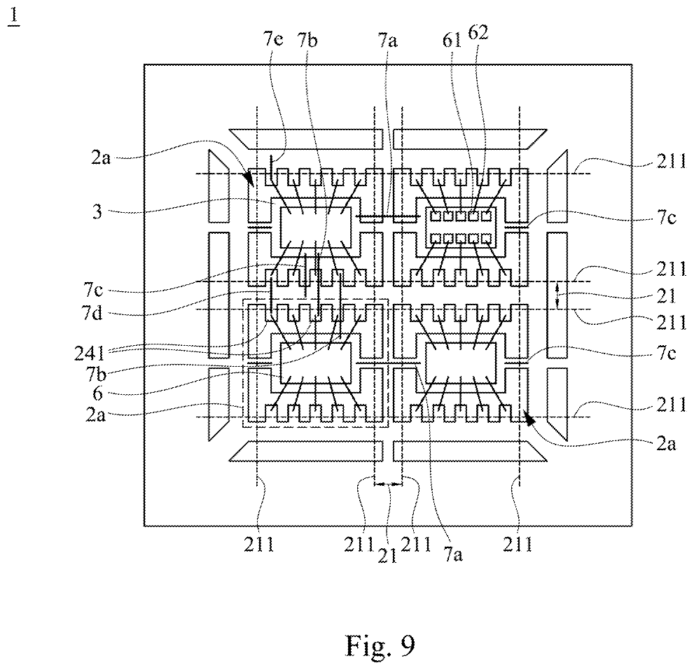

Please refer FIGS. 8A, 8B, and 9. The semiconductor package substrate module 1 includes a substrate 2, a plurality of semiconductor package assemblies 1a, and an encapsulating body 8. The substrate 2 includes a plurality of cutting areas 21, and the cutting area 21 separates the substrate 2 onto plural substrate units 2a. The package assemblies include the substrate units 2a, a plurality of chips 6, a plurality of first wires 62, and a plurality of second wires 7. The substrate unit 2a includes a plurality of first electrical contact points 24 and at least one grounding transfer area 3. The first electrical contact points 24 include a plurality of first signal contact points 242 and a plurality of first ground contact points 241. The first electrical contact points 24 and the at least one grounding transfer area 3 are disposed on the first surface 22 of the substrate units 2a. Each chip 6 includes a plurality of second electrical contact points 61. The chips 6 are disposed on the first surfaces 22 of the substrate units 2a. The chips 6 are further disposed in each grounding transfer area 3. The first wires 62 electrically connect to the first electrical contact points 24 of the substrate units 2a and the second electrical contact points 61 of the chips 6. One end of the at least one second wire 7 connects to at least one grounding transfer area 3 or the first ground contact points 241, and the other end of the at least one second wire 7 extends toward the cutting areas 21. The encapsulating body 8 encapsulates the substrate 2, the chip 6, the first wires 62, and the second wire 7.

In one embodiment, one end of the second wire 7a is fixed to at least one grounding transfer area 3 of the substrate unit 2a, and the other end of the second wire 7a extends toward the cutting area 21 and then extends to another adjacent substrate unit 2a. The other end of the second wire 7a is fixed to the grounding transfer area 3 of another adjacent substrate unit 2a, so that the second wire 7a crosses the cutting area 21. The two ends of the second wire 7a are disposed in the grounding transfer areas 3 in the substrate units 2a on both sides of the cutting area 21, respectively. The configuration of the second wire 7 in the two semiconductor package assemblies 1a may be completed simultaneously by using only one wire, thereby greatly shortening the time for manufacturing the second wire 7a.

In one embodiment, one end of the second wire 7b is fixed to at least one grounding transfer area 3 of the substrate unit 2a, and the other end of the second wire 7b extends toward the cutting area 21, and then extends to another adjacent substrate unit 2a. The other end of the second wire 7b is fixed to the first ground contact point 241 of another adjacent substrate unit 2a. In yet another embodiment, one end of the second wire 7b is fixed to the first ground contact point 241 of the substrate unit 2a, and the other end of the second wire 7b extends toward the cutting area 21, and then extends to another adjacent substrate unit 2a. The other end of the second wire 7b is fixed to the grounding transfer area 3 of another adjacent substrate unit 2a, so that the second wire 7b spans the cutting area 21. The two ends of the second wire 7b are disposed in the grounding transfer area 3 and the first ground contact point 241 in the substrate units 2a on both sides of the cutting area 21, respectively. The configuration of the second wire 7 in the two semiconductor package assemblies 1a may be completed simultaneously by using only one wire, thereby greatly shortening the time for manufacturing the second wire 7b. In addition, when the second wire 7 is fixed at the first ground contact point 241, a portion of the bonding range of the first wires 62 may be avoided, thereby preventing the problem of overlapping interference between the first wires 62 and the second wire 7, and making the configuration of the second wire 7b more flexible.

In one embodiment, one end of the second wire 7c is fixed to at least one grounding transfer area 3 of the substrate unit 2a, and the other end of the second wire 7 extends toward the cutting area 21. The other end of the second wire 7c is fixed in the cutting area 21, so that the second wire 7c forms a structure extending outward from the substrate unit 2a. Since the grounding transfer area 3 has a large area, the second wire 7c may extend from any position of the grounding transfer area 3 to surrounding cutting area 21, thereby simply avoiding the first wires 62 connecting between the chip 6 and the first electrical contact point 24, and avoiding the first wires 62 interleaved with the second wire 7c. Therefore, the second wire 7c may be freely disposed in the corresponding positions of the grounding transfer area 3 and the cutting area 21 according to the actual wiring situation.

In one embodiment, one end of the second wire 7d is fixed to the first ground contact point 241 of the substrate unit 2a, and the other end of the second wire 7d extends toward the cutting area 21 to another adjacent substrate unit 2a. The other end of the second wire 7d is fixed to the first ground contact point 241 of another adjacent substrate unit 2a, so that the second wire 7d spans the cutting area 21 between two adjacent substrate units 2a. The two ends of the second wire 7d are disposed at the first ground contact points 241 in the substrate units 2a on both sides of the cutting area 21. A structure in which the second wire 7d in two groups of the substrate units 2a extends toward the cutting area 21 may be obtained through one wire bonding process. This method has the effect of reducing the process and shortening the process time.

In one embodiment, one end of the second wire 7e is fixed to the first ground contact point 241 of the substrate unit 2a, and the other end of the second wire 7e extends toward the cutting area 21, and then the other end of the second wire 7e is fixed in the cutting area 21. The two ends of the second wire 7e are fixed on both sides of the cutting line 211 between the substrate unit 2a and the cutting area 21. The length of the second wire 7 here may be designed shorter according to the distance between the first ground contact point 241 and the cutting area 21. The connection way of the second wire 7 does not need to span the entire the cutting area 21 to avoid wire collapse when the second wire 7e spans a long distance, a short circuit caused by contacting with a substrate, or even a short circuit caused by interlacing with other welding wires, thereby improving the reliability of production. The second wires 7e are fixed on both sides of the cutting line 211 may save the usage of the second wire 7 and greatly lower the cost.

After the second wire 7 on the substrate unit 2a is fixed, the substrate 2 is encapsulated by the encapsulating body 8, and the encapsulating body 8 covers the first electrical contact point 24, grounding transfer area 3, the chip 6, the first wires 62, and the second wire 7 which are disposed on the first surface 22. The various components on the first surface 22 are protected, fixed, and insulated by the encapsulating body 8. After the encapsulating body 8 is solidified, each semiconductor package assembly 1a is cut from the substrate 2 along the cutting line 211 with a knife to form an independent semiconductor package assembly 1a. The encapsulating body 8 in each semiconductor package assembly 1a forms a side surface along the cutting line 211. The second wire 7 spanning the cutting line 211 is exposed from the side surface of the encapsulating body 8 formed along the cutting line 211 and is in contact with the air. Because the wire diameter of the second wire 7 is small, when the second wire 7 is exposed from the side surface of the encapsulating body 8, the second wire 7 only shows small, less visible dot that will not affect the surface appearance of the encapsulating body 8.

The encapsulating body 8 may be an insulating material of epoxy molding compound. The encapsulating body 8 may isolate the components on the first surface 22 form external electrical contacts. Only the exposed second wire 7 may provide electrical neutralization and grounding functions for electrostatically charge objects. Since the grounding transfer area 3 or the first ground contact points 241 connected by the second wire 7 on the first surface 22 are all grounded, the second wire 7 has a ground voltage. When an electrostatically charge object approaches the second wire 7, the air near the tip of the second wire 7 is dissociated into an ion state due to a higher electric field, and the air molecules in the ion state are conductive, so the air in the ion state may be regarded as a conductor. Therefore, the flow of electrons is generated between the object with static electricity and the second wire 7, and then the second wire 7 is used to neutralize the object with static electricity, thereby reducing the damage of static electricity to the semiconductor package assembly 1a. When an object charged with static electricity the contacts the semiconductor package assembly 1a, the second wire 7 is made of metal and is exposed from the surface of the encapsulating body 8 and the resistance value of the second wire 7 is smaller than that of the encapsulating body 8, so the second wire 7 may quickly ground the electrostatic guide of the object charged with static electricity, thereby avoiding the object charged with static electricity causing damage to the semiconductor package assembly 1a.

Through the disclosure of the above embodiments, the disposing of the second wire 7 may effectively improve the influence of electrostatic discharged on the semiconductor package assembly 1a. The second wire 7 may produce corona discharge to the object with static electricity without contact, and the second wire 7 may ground the object with static electricity when it is in contact, which has a better effect on electrostatic discharge and avoid the semiconductor package assembly 1a due to static electricity discharge damage. Moreover, since the second wire 7 has a small wire diameter and is only disposed on the side surface of the encapsulating body 8, it is not particularly conspicuous in appearance. Besides, the additional design of the second wire 7 does not change the arrangement of the original working components in the semiconductor package assembly 1a. The original shape and characteristics of the semiconductor package assembly 1a may be maintained as well as the electrostatic protection function may be increased.

What is claimed is:

1. A semiconductor package assembly, comprising:
a substrate comprising a plurality of first electrical contact points and at least one grounding transfer area, the plurality of first electrical contact points comprising a plurality of first ground contact points, and the plurality of first ground contact points and the at least one grounding transfer area disposed on a first surface of the substrate;
a chip comprising a plurality of second electrical contact points, the chip disposed on the first surface of the substrate;
a plurality of first wires respectively electrically connecting to the corresponding plurality of first electrical contact points of the substrate and the corresponding plurality of second electrical contact point of the chip;
one end of at least one second wire connecting to the at least one grounding transfer area or one of the plurality of first ground contact points; and
an encapsulating body encapsulating the first surface of the substrate, the chip, and the at least one second wire, the encapsulating body forming at least one surface on the substrate, the other end of the at least one second wire extending to and exposed from the at least one surface of the encapsulating body.

2. The semiconductor package assembly of claim 1, wherein the at least one grounding transfer area comprises at least one grounding transfer pad connecting to a ground voltage, and the least one grounding transfer pad is adjacent to one side of the substrate.

3. The semiconductor package assembly of claim 2, wherein the substrate comprises a plurality of contact pads disposed on one side of a second surface of the substrate, and the second surface is opposite to the first surface.

4. The semiconductor package assembly of claim 3, further comprising a protective element and a control component disposed on the substrate, the contact pads comprising at least one ground contact pad electrically connecting to the at least one grounding transfer pad, and the protective element electrically connecting to the at least one grounding transfer pad and the control component.

5. The semiconductor package assembly of claim 3, further comprising a control component disposed on the substrate, the contact pads comprising a plurality of ground contact pads electrically connecting to the at least one grounding transfer pad, and the at least one grounding transfer pad being direct electrically connecting to the control component.

6. The semiconductor package assembly of claim 1, wherein the chip is a memory module.

7. The semiconductor package assembly of claim 1, wherein the substrate is a circuit board or a lead frame.

8. The semiconductor package assembly of claim 1, further comprising a ground wire disposed on the substrate and adjacent to an edge of the substrate, and the ground wire connecting to a ground voltage.

9. A semiconductor package substrate module, comprising:
a substrate comprising a plurality of cutting areas separating the substrate into a plurality of substrate units;
a plurality of semiconductor package components, and each one of the plurality of semiconductor package components comprising:
one of the plurality of substrate units;
a plurality of first electrical contact points and at least one grounding transfer area disposed on a first surface of the substrate unit, the plurality of first electrical contact points comprising a plurality of first signal contact points and a plurality of first ground contact points;
a chip comprising a plurality of second electrical contact points, the chip disposed on the first surface of the substrate unit;
a plurality of first wires electrically connecting to the corresponding plurality of first electrical contact points and the corresponding plurality of second electrical contact points; and
one end of at least one second wire connecting to the at least one grounding transfer area or the plurality of first ground contact points and the other end of the at least one second wire extending toward the plurality of cutting areas; and
an encapsulating body encapsulating the substrate and the plurality of semiconductor package components.

10. The semiconductor package substrate module of claim 9, wherein the other end of the at least one second wire is fixed on the plurality of cutting areas.

11. The semiconductor package substrate module of claim 9, wherein the other end of the at least one second wire extends from the plurality of cutting areas to the adjacent plurality of substrate units, and the other end of the at least one second wire is fixed to the at least one grounding transfer area or the plurality of first ground contact points in the adjacent plurality of substrate units.

12. The semiconductor package substrate module of claim 9, wherein the at least one grounding transfer area comprises at least one grounding transfer pad connecting to a ground voltage, and the at least one grounding transfer pad is adjacent to one side of the substrate.

13. The semiconductor package substrate module of claim 12, wherein each one of the plurality of substrate units comprises a plurality of contact pads disposed on one side of a second surface of the substrate unit, and the second surface is opposite to the first surface.

14. The semiconductor package substrate module of claim 13, wherein each one of the plurality of substrate units comprises a protective element and a control component, the contact pads comprises a plurality of ground contact pads electrically connecting to the at least one grounding transfer pad, and the protective element electrically connects to the at least one grounding transfer pad and the control component.

15. The semiconductor package substrate module of claim 13, wherein each one of the plurality of substrate units comprises a control component, the contact pads comprises a plurality of ground contact pads electrically connecting to the at least one grounding transfer pad, and the at least one grounding transfer pad directly electrically connects to the control component.

16. The semiconductor package substrate module of claim 9, wherein the substrate is a circuit board or a lead frame.

17. The semiconductor package substrate module of claim 9, wherein the chips are a plurality of memory modules.

18. The semiconductor package substrate module of claim 9, wherein each one of the plurality of semiconductor package components further comprises a ground wire disposed on the substrate unit and adjacent to an edge of the substrate unit, and the ground wire connects to a ground voltage.
